(19) United States
(12) Patent Application Publication
(10) Pub. No.: US 2025/0180622 A1
(43) Pub. Date: Jun. 5, 2025

(54) MULTI-FAULT DIAGNOSIS METHOD FOR POWER DISTRIBUTION NETWORK, AND SYSTEM

(71) Applicant: DONGGUAN POWER BUREAU OF GUANGDONG POWER GRID CO., LTD., Dongguan (CN)

(72) Inventors: Jinman LUO, Dongguan (CN); Zhonglu ZOU, Dongguan (CN); Xiliang DAI, Dongguan (CN); Zhuxin ZHAI, Dongguan (CN); Piao LIU, Dongguan (CN); Ling YU, Dongguan (CN); Zirui YAO, Dongguan (CN); Chengfang GAO, Dongguan (CN); Xiongrong DENG, Dongguan (CN); Zhuoxian LIU, Dongguan (CN); Liyuan LIU, Dongguan (CN); Siqi YE, Dongguan (CN); Yanji ZHOU, Dongguan (CN)

(21) Appl. No.: 18/862,236

(22) PCT Filed: Nov. 24, 2022
(86) PCT No.: PCT/CN2022/133889

§ 371 Date: Nov. 1, 2024

(30) Foreign Application Priority Data
May 11, 2022 (CN) 202210506365.6

(51) Int. Cl. G01R 31/08; G06N 3/0985

(52) U.S. Cl. CPC G01R 31/088; G01R 31/086; G06N 3/0985

(57) ABSTRACT

A multi-fault diagnosis method for a power distribution network is provided. The method includes: performing short-circuit fault analysis on a line of a power distribution network by using a MATLAB platform, so as to obtain an electrical quantity-based fault information decision table; performing modeling and simulation on the fault information decision table by using a Simulink platform; denoising and collecting output training data of a neural network of the power distribution network by using a wavelet transformation method, and forming a related fault information decision table as a training sample of the neural network; and optimizing weights and thresholds of the neural network by using an improved Artificial Tree intelligent optimization algorithm, selecting some of the data as fault data, and using the neural network trained to perform fault detection.

This application claims priority to a Chinese patent application filed with the China National Intellectual Property Administration (CNIPA) on May 11, 2022, with application number No. 202210506365.6, the content of which is incorporated herein by reference in its entirety.

### TECHNICAL FIELD

The present application relates to the field of fault diagnosis technology for a power distribution network, and specifically to a multi-fault diagnosis method for a power distribution network, and a system.

### BACKGROUND

Electric energy has become an indispensable and important resource in human life. Once a fault occurs during the operation of a power grid, it will cause huge losses to social production and people's lives. Therefore, when the power grid fails, necessary measures should be taken to quickly and accurately locate the area where the fault occurs, find out the specific fault line, and improve the speed of power supply restoration and detection accuracy after the power grid fails.

The fault detection system for a power distribution network further has the following defects:
(1) The signal collection device and other protection devices in the actual power distribution network are susceptible to interference from human or various electromagnetic devices, resulting in many uncertain factors in the power distribution network, so the fault detection method cannot timely locate and detect the fault during a dynamical change of lines, and has a poor fault tolerance when fault information includes mal-operation information.

(2) After the topology planning for fault detection is completed, when the structure of the actual power grid and related protection devices change, the topology of the network can be hardly changed but needs to be redesigned, which makes the actual operation very cumbersome.

### SUMMARY

An object of the present application is to provide a multi-fault diagnosis method for a power distribution network and a system to solve the technical problems in the related technology that when the lines change dynamically, the fault cannot be located and detected timely, and when the fault information includes mal-operation information, the fault tolerance is poor and the topology planning is cumbersome.

To solve the above technical problems, the following technical solutions are provided according to the present application:

A multi-fault diagnosis method for a power distribution network includes the following steps:

In step S1, short-circuit fault analysis is performed on lines of a power distribution network by using a MATLAB platform to obtain an electrical quantity-based fault information decision table.

In step S2, modeling and simulation are performed on the electrical quantity-based fault information decision table by using a Simulink platform, and output training data of a neural network of the power distribution network are acquired.

In step S3, the output training data of the neural network is de-noised and collected by using a wavelet transformation method, and a related fault information decision table is formed and used as a training sample of the neural network.

In step S4, weights and thresholds of the neural network are optimized by using an improved Artificial Tree intelligent optimization algorithm to satisfy the requirement related to error accuracy by means of iteration, some of the data as fault data are selected, and the neural network trained is used to perform fault detection.

As a solution of the present application, in step S1, the MATLAB platform collects a zero-sequence current signal, a zero-sequence power signal and a zero-sequence admittance signal generated by a low-current ground short circuit fault occurring in the lines of the power distribution network, and an electrical quantity-based fault information decision table is formed on the basis of these three types of information.

As a solution of the present application, fault analysis is performed on the basis of the zero-sequence current signal, the zero-sequence power signal and the zero-sequence admittance signal by using a sampling mode with a mixture of discrete sampling time and continuous sampling time, which includes the following:

In step S201, positive and negative zero-sequence currents at one of two terminals of each line are sampled and stored.

In step S202, a sampled current within a time window of fixed length is selected as a line reference current, a dynamic sampled current is compared with the line reference current, and a correlation coefficient between the two in real time is solved by using an improved Pearson method.

In step S203, a correlation coefficient threshold is set, it is determined which of magnitudes of the correlation coefficient and the threshold set is larger, and a line where a fault is located and the type of the fault are outputted.

As a solution of the present application, in step S1, the improved Pearson method adopts a cumulative value of the line correlation coefficient to perform correlation coefficient analysis for fault detection. The improved Pearson method includes the following:

In step S2021, movable window values T_{det} and Toc in a time window with a fixed length are defined, where end fixed moments of the window values T_{det} and T_{loc} are ty and t₂ respectively, a sampled current in T_{det} is compared with a steady-state reference current to detect a fault of a direct current micro-grid. A relational expression between T_{det} and T_{loc} is as follows:

$${n}_{s} / {f}_{s} \leq {T}_{loc} \leq {T}_{0} \leq {T}_{det} ,$$

fₛ is a sampling frequency of a line current, nₛ is the number of sampling points, and T₀ is the duration from a time to when the fault occurs to the time t₂ when the fault is detected.

In step S2022, correlation coefficient analysis is performed for fault detection by using the cumulative value of the line correlation coefficient, where i^{th} comparison values of a steady-state reference current curve and a sampled current curve are expressed as P_{1_i} and P_{2_i}, respectively:

$$\{ \begin{matrix}{P}_{1 \_ i} = {\sum }_{j = 1}^{i} {I}_{ref \_ j} \\ {P}_{2 \_ i} = {\sum }_{j = 1}^{i} {I}_{sam \_ j}\end{matrix} ,$$

I_{ref_j} is an i^{th} transient line current, and I_{sam_j} is an i^{th} sampled line current.

In step S2023, an adjustment factor p is introduced to optimize a correlation coefficient in the Pearson method. The expression of the adjustment factor p is as follows:

$$p = 2 \times [ 1 - {( 1 + {- \vert {\sum }_{i = 1}^{n} \vert {P}_{1 \_ i} - {P}_{2 \_ i} \vert {/}_{n} \vert}^{} )}^{- 1} ]$$

[symbol] is a mathematical constant and is expressed as the base of the natural logarithm, and n is the total number of points at which the two curves are compared.

In step S2023, a correlation coefficient r is optimized according to the adjustment factor p, and the expression of the correlation coefficient r is as follows:

$$\begin{matrix}r = p \times {r}_{0} \\ {r}_{0} = \frac{{\sum }_{i = 1}^{2} [ {P}_{1 \_ i} - \frac{1}{n} {\sum }_{j = 1}^{n} {P}_{1 \_ i} ) ( ( {P}_{2 \_ i} - \frac{1}{n} {\sum }_{j = 1}^{n} {P}_{2 \_ i} ) ]}{\sqrt{{\sum }_{j = 1}^{n} {( {P}_{1 \_ i} - \frac{1}{n} {\sum }_{j = 1}^{n} {P}_{1 \_ i} )}^{2}} \sqrt{{\sum }_{j = 1}^{n} {( {P}_{2 \_ i} - \frac{1}{n} {\sum }_{j = 1}^{n} {P}_{2 \_ i} )}^{2}}}\end{matrix}$$

As a solution of the present application, in step S2, a fault location and a fault resistance are obtained according to the fault analysis, the output training data of the model is constructed through the Simulink platform, and the training data is processed by the wavelet transformation method.

As a solution of the present application, processing the training data by the wavelet transformation method includes the following.

In step S301, wavelet transformation is performed on a training data signal f(t) with noise to obtain a set of decomposed wavelet coefficients.

In step S302, threshold processing is performed on the obtained decomposed wavelet coefficients by using a soft threshold function to obtain a set of estimated wavelet coefficients, and the expression of the soft threshold function ν(ω) is as follows:

$$\begin{matrix}υ ( ω ) = \{ \begin{matrix}( \vert ω \vert - T ) sign ( ω ) , \vert ω \vert \geq T \\ ω \times d \times {a}^{- {b ( \vert ω \vert - T )}^{2}} , \vert ω \vert < T\end{matrix} , and \\ T = σ \sqrt{2 In ( m )} .\end{matrix}$$

sign is a sign function, ω is a wavelet coefficient, T is the threshold, σ is a noise intensity, m is a signal length, d is an amplitude factor, and a and b are adjustment factors.

In step S303, by adjusting d, the soft threshold function is enabled to be continuous at the threshold point T and an oscillation error generated to the original signal is reduced, and a denoised signal is extracted.

As a solution of the present application, in step S4, a mean square error of the oscillation error is optimized by using the Artificial Tree algorithm to obtain a line neural network. The optimization by using the Artificial Tree algorithm is as follows.

In step S401, the mean square error MSE of the oscillation error is used as an objective function, collected data is sorted, and training samples and test samples are prepared.

In step S402, relevant parameters of the Artificial Tree algorithm are set, the number SN of branches, the number D of spatial dimensions, and the number tₘₐₓ of iterations are determined, and an initialization operation is performed on the branches to generate an initial branch.

In step S402, a function value corresponding to each branch is calculated, and the best branch x_{best} and the function value f(x_{best}) corresponding to the best branch are selected according to the function value.

In step S403, it is determined whether the requirement related to error accuracy is satisfied or whether the maximum number of iterations is reached, and if neither of the precedings is satisfied, it is prepared to enter an iterative optimization process by an iterated local search (IAT) algorithm.

In step S404, if a search number reaches an upper limit of the search number, a random operation is performed to generate a new branch, and the newly-generated branch is compared with an old branch, and if the new branch is better than the old branch, the old branch is replaced with the new branch; otherwise, the old branch is still taken as the best branch.

In step S405, it is determined whether the best branch satisfies the requirement related to error accuracy or whether the current number of iterations reaches the set maximum number tₘₐₓ of iterations.

As a solution of the present application, the relevant parameters of the Artificial Tree algorithm are set according to operation information of protection devices of the lines of the power distribution network and a corresponding fault area, to form a corresponding training sample of the neural network.

As a solution of the present application, the operation information of protection devices of the lines of the power distribution network is mainly collected power grid signals based on switch quantities, and power grid switch operations are numbered with 0 and 1.

A system applying a multi-fault diagnosis method for a power distribution network, includes a circuit sampling module, a line protection device, a fault analysis module, a simulation module and a detection output module.

The circuit sampling module is configured to collect and pre-process various data imported into the MATLAB platform and the Simulink platform.

The line protection device is configured to perform corresponding protection operations such as tripping or alarming when a fault occurs in the power distribution network, determine, according to different protection operations of the protection device, an approximate section in which the fault occurs, and number sections of the power distribution grid.

The fault analysis module is configured to analyze a fault location and a fault resistance value, and determine an approximate fault area.

The simulation module is configured to acquire fault detection data through the Artificial Tree intelligent optimization algorithm by using the Simulink platform and display a simulation result.

The detection output module is configured to, according to the simulation result, select part of the data to detect accuracy of power grid fault detection by the line neural network, analyze and report adaptability.

Compared with the related technologies, this application has the following beneficial effects.

In this application, the MATLAB platform is utilized and an improved wavelet threshold denoising method is used to remove noise sources in the signals to establish a power grid fault model, improve signal acquisition accuracy, simulation software is run for simulation, and a power grid fault model is established based on switch quantities to obtain a power grid fault information decision table; a neural network is trained, the section where the fault occurs is detected, and a divide-and-conquer strategy for complex power grids is adopted, so that the line topology structure can be flexible and changeable. This not only improves the accuracy and reliability of power grid fault diagnosis, but also can detect faults when there is mal-operation information in the fault information, thereby achieving the effect of locating fault areas in the power grid and effectively enhancing the capability of detecting faults of the power grid.

### BRIEF DESCRIPTION OF DRAWINGS

FIG. 1 is a flow chart of a multi-fault diagnosis method for a power distribution network according to an embodiment of the present application;

FIG. 2 is a schematic diagram of a dynamic fault detection time axis according to an embodiment of the present application; and

FIG. 3 is a structural block diagram of a fault detection system according to an embodiment of the present application.

### REFERENCE NUMERAL LIST

1 circuit sampling module
2 line protection device
3 fault analysis module
4 simulation module
5 detection output module

### DETAILED DESCRIPTION

Technical solutions in embodiments of the present application are described clearly and completely hereinafter in conjunction with the drawings in the embodiments of the present application. The described embodiments are only part of the embodiments of the present application rather than all embodiments.

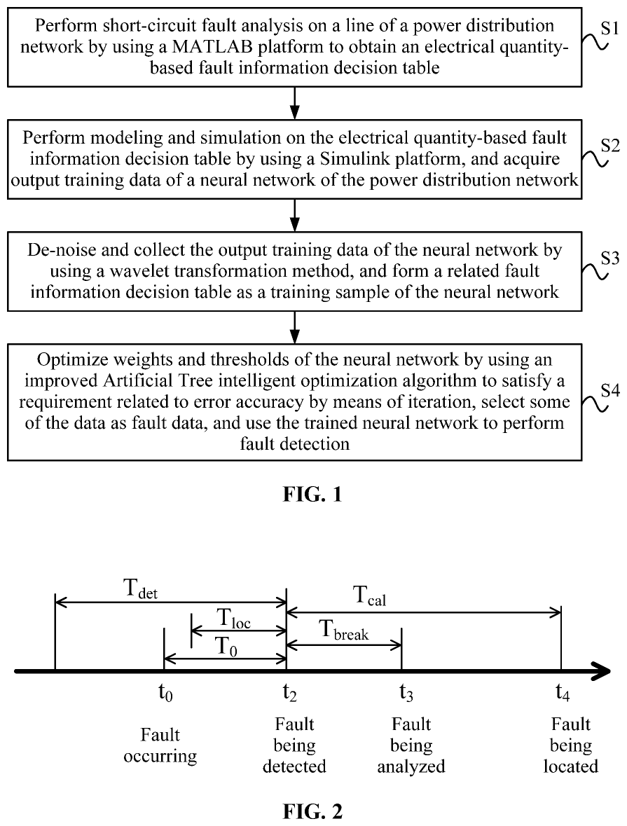

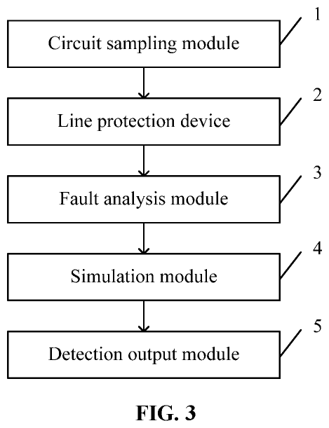

As shown in FIG. 1 to FIG. 3, a multi-fault diagnosis method for a power distribution network is provided according to the present application, which includes the following steps:

In step S1, short-circuit fault analysis is performed on lines of the power distribution network by using a MATLAB platform to obtain an electrical quantity-based fault information decision table.

In step S2, modeling and simulation are performed on the electrical quantity-based fault information decision table by using a Simulink platform, and output training data of a neural network of the power distribution network is acquired.

In step S3, the output training data of the neural network is denoised and collected by using a wavelet transformation method, and a related fault information decision table is formed as a training sample of the neural network.

In step S4, weights and thresholds of the neural network are optimized by using an improved Artificial Tree intelligent optimization algorithm to satisfy a requirement related to error accuracy by means of iteration, some of the data is selected as fault data, and the trained neural network is used to perform fault detection.

In this embodiment, a power grid fault model is established according to data of lines of the power distribution network, and data as input required for training the neural network is collected. While collecting information, the collected data is de-noised by using the wavelet transformation theory to remove the noise source that adversely affects the accuracy of the data. Then, the de-noised data is collected to form a relevant fault information decision table as the training sample of the neural network. The Artificial Tree intelligent optimization algorithm is applied to optimize weights and thresholds of the neural network. The requirement related to error accuracy is satisfied through iteration. Some of the data is selected as fault data and the neural network trained is used to perform fault detection.

In step S1, the MATLAB platform collects a zero-sequence current, a zero-sequence power and a zero-sequence admittance signal generated by a low-current ground short circuit fault in the lines of the power distribution network, and an electrical quantity-based fault information decision table is formed on the basis of these three types of information.

In this embodiment, when a neural network is used to solve the problem of power grid fault detection, operation information of protection devices is used as input values of the neural network and the corresponding fault area is used as an output value to form a corresponding training sample of the neural network, which is used to establish a detection model.

Fault analysis is performed on the basis of the zero-sequence current, the zero-sequence power and the zero-sequence admittance signal by using a sampling mode with a mixture of discrete sampling time and continuous sampling time, which includes the following.

In step S201, positive and negative zero-sequence currents are sampled and stored at one of two terminals of each line.

In step S202, a sampled current within a time window of fixed length is selected as a line reference current, a dynamic sampled current is compared with the line reference current, and a correlation coefficient between the two is solved in real time by using an improved Pearson method.

In step S203, a correlation coefficient threshold is set, it is determined which of magnitudes of the correlation coefficient and the threshold set is larger, and a line where a fault is located and the type of the fault are output.

In this embodiment, if the current correlation degree of one of the positive and negative poles is lower than the threshold, and the sum of the currents of the two poles in the line is not zero, it is considered that the line has a pole-to-ground short circuit fault; if the current correlation degrees of the positive and negative poles of the line are both lower than the threshold, and the sum of the currents of the two poles in the line is approximately zero, it is considered that the line has an inter-pole short circuit fault; otherwise, it is considered that the line has no fault.

In this embodiment, the power grid fault protection consists of three parts: fault detection, fault isolation and fault location. As shown in FIG. 2, assuming that a short circuit fault occurs at a moment t₁, the current of the fault line increases rapidly. The fault may be detected by the fault detection device at a certain moment later which is defined as a moment t₂. From the moment t₂, fault isolation and fault location are carried out synchronously: in one aspect, a fault isolation device starts to operate and successfully disconnects the fault line at a later moment t₃; and in the other aspect, a fault location device starts to predict the location of the fault and gives a predicted location of the fault at a later moment t₄. By analyzing the time sequence of the various parts in the fault protection, it can be found as follows.

First, the fault isolation can be operated only after the fault is detected. Since the direct current micro-grid fault isolation needs to be completed within a few milliseconds, the system has high requirements for the rapidity of fault detection.

Second, the fault location is started synchronously with the fault isolation after the fault is detected, and the two processes of fault location and fault isolation are decoupled from each other, so the system does not have high requirements for the rapidity of fault location.

Third, since the line current change after the fault isolation device operates is related to the operation of the fault isolation device and is hardly predicted, only the system state quantities before the fault is detected are high-quality data for fault detection and fault location.

In step S202, the improved Pearson method adopts a cumulative value of the line correlation coefficient to perform correlation coefficient analysis for fault detection. The improved Pearson method includes the following steps.

In step S2021, movable window values T_{det} and T_{loc} in a time window with a fixed length are defined, where end fixed moments of the window values T_{det} and T_{loc} are t₁ and t₂ respectively, a sampled current in T_{det} is compared with a steady-state reference current to detect a fault of a direct current micro-grid. A relational expression between T_{det} and T_{loc} is as follows:

$${n}_{s} / {f}_{s} \leq {T}_{loc} \leq {T}_{0} \leq {T}_{det} ,$$

fₛ is a sampling frequency of a line current, nₛ is the number of sampling points, and T₀ is the duration from a time t₀ when the fault occurs to the time t₂ when the fault is detected.

In step S2022, correlation coefficient analysis is performed for fault detection by using the cumulative value of the line correlation coefficient, where i^{th} comparison values of a steady-state reference current curve and a sampled current curve are expressed as P_{1_i} and P_{2_i}:

$$\{ \begin{matrix}{P}_{1 \_ i} = {\sum }_{j = 1}^{i} {I}_{ref\_j} \\ {P}_{2 \_ i} = {\sum }_{j = 1}^{i} {I}_{sam\_j}\end{matrix}$$

I_{ref_j} is an i^{th} transient line current, and I_{sam_j} is an i^{th} sampled line current.

In step S2023, an adjustment factor p is introduced to optimize a correlation coefficient in the Pearson method. The expression of the adjustment factor p is as follows:

$$p = 2 \times [ 1 - {( 1 + {- \vert {\sum }_{i = 1}^{n} \vert {P}_{1 \_ i} - {P}_{2 \_ i} \vert {/}_{n} \vert}^{} )}^{- 1} ]$$

[symbol] is a mathematical constant and is expressed as the base of the natural logarithm, and n is the total number of points at which the two curves are compared.

In step S2023, a correlation coefficient r is optimized according to the adjustment factor p, and the expression of the correlation coefficient r is as follows:

$$\begin{matrix}r = p \times {r}_{0} \\ {r}_{0} = \frac{{\sum }_{i = 1}^{n} [ ( {P}_{1 \_ i} - \frac{1}{n} {\sum }_{j = 1}^{n} {P}_{1 \_ i} ) ( ( {P}_{2 \_ i} - \frac{1}{n} {\sum }_{j = 1}^{n} {P}_{2 \_ i} ) ]}{\sqrt{{\sum }_{j = 1}^{n} {( {P}_{1 \_ i} - \frac{1}{n} {\sum }_{j = 1}^{n} {P}_{1 \_ i} )}^{2}} \sqrt{{\sum }_{j = 1}^{n} {( {P}_{2 \_ i} - \frac{1}{n} {\sum }_{j = 1}^{n} {P}_{2 \_ i} )}^{2}}}\end{matrix}$$

In this embodiment, in step S2022, if the sampled current and the steady-state calculated current are directly compared, the correlation coefficient will change with the change of the current ripple, and a large number of false detections may occur. To prevent the occurrence of false detection, the cumulative value of the line is used to perform the correlation coefficient analysis for fault detection to eliminate the interference caused by this phenomenon and the low accuracy of fault locating resulted therefrom.

In this embodiment, the sampled current and the steady-state reference current are compared during fault detection, and the improved Pearson method is used to solve the correlation coefficient between these two in real time. When the correlation coefficient drops below the set threshold, it is considered that a short circuit fault occurs, and the fault line and the type of the fault are output.

In this embodiment, an iterative method based on a genetic algorithm is used in fault location to realize generation and update of the predicted fault location and fault impedance, the fault current curve corresponding to the predicted fault location and fault impedance is calculated, and the improved Pearson method is used to solve the correlation coefficient between the sampled curve and the calculated curve. When the correlation coefficient rises above the set threshold, it is considered that the predicted fault location and fault impedance are sufficiently accurate, and the predicted fault location and fault impedance are output.

In step S2, a fault location and fault resistance are obtained according to the fault analysis, a model is constructed through the Simulink platform to output training data, and the training data is processed by the wavelet transformation method.

The wavelet transformation method processes the training data in the following manner:
In step S301, wavelet transformation is performed on a training data signal f(t) with noise to obtain a set of decomposed wavelet coefficients;
In step S302, threshold processing is performed on the obtained decomposed wavelet coefficients by using a soft threshold function to obtain a set of estimated wavelet coefficients, and the expression of the soft threshold function ν(ω) is as follows:

$$\begin{matrix}υ ( ω ) = \{ \begin{matrix}( \vert ω \vert - T ) sign ( ω ) , \vert ω \vert \geq T \\ ω \times d \times {a}^{- {b ( \vert ω \vert - T )}^{2}} , \vert ω \vert < T\end{matrix} , and \\ T = σ \sqrt{2 In ( m )} .\end{matrix}$$

sign is a sign function, ω is a wavelet coefficient, T is the threshold, σ is a noise intensity, m is a signal length, d is an amplitude factor, and a and b are adjustment factors.

In step S303, by adjusting d, the soft threshold function is enabled to be continuous at the threshold point T and an oscillation error generated to the original signal is reduced, and the de-noised signal is extracted.

In this embodiment, the value of the wavelet coefficient caused by the noise source is less than the preset critical threshold, while the value of the wavelet coefficient caused by the original signal is greater than the preset critical threshold. By using this characteristic, the noise signal with a wavelet coefficient less than the critical threshold is removed, the original signal with a wavelet coefficient greater than the critical threshold is retained, and then the inverse wavelet transformation is performed to reconstruct the signal to achieve the purpose of denoising.

In this embodiment, the flexibility of usage of the threshold function is enhanced by adjusting the values of a and b. The parameter d determines the approximation degree of the threshold. By adjusting d, the soft threshold function is enabled to be continuous at the threshold point T and the oscillation error generated to the original signal is reduced so that the extracted de-noised original signal is more accurate and more reliable, thus improving the accuracy of denoising the fault signal in power grid fault detection, thereby improving the accuracy of power grid fault detection.

In step S4, a mean square error of the oscillation error is optimized by using the Artificial Tree algorithm to obtain a line neural network. The optimization using the Artificial Tree algorithm includes the following.

In step S401, the mean square error MSE of the oscillation error is used as an objective function, and training samples and test samples are prepared by sorting collected data.

In step S402, relevant parameters of the Artificial Tree algorithm are set, the number SN of branches, the number D of spatial dimensions, and the number tₘₐₓ of iterations are determined, and an initialization operation is performed on the branches to generate an initial branch.

In step S402, a function value corresponding to each branch is calculated, and the best branch x_{best} and the function value f(x_{best}) corresponding to the best branch are selected according to the function value.

In step S403, it is determined whether the requirement related to error accuracy is satisfied or whether the maximum number of iterations is reached, and if neither requirement is satisfied, it is prepared to enter an iterative optimization process by an IAT algorithm.

In step S404, if a search number reaches an upper limit of search number, a random operation is performed to generate a new branch, the newly-generated branch is compared with an old branch, and if the new branch is better than the old branch, the old branch is replaced with the new branch, otherwise, the old branch is still taken as the best branch.

In step S405, it is determined again whether the best branch satisfies the requirement related to error accuracy or whether the current number of iterations reaches the set maximum number tₘₐₓ of iterations.

The relevant parameters of the Artificial Tree algorithm are set according to the operation information of protection devices of the lines of the power distribution network and a corresponding fault area, to form a corresponding training sample of the neural network.

The operation information of protection devices of the lines of the power distribution network is mainly collected power grid signals based on switch quantities, and power grid switch operations are numbered with 0 and 1.

A system applying a multi-fault diagnosis method for a power distribution network, includes a circuit sampling module 1, a line protection device 2, a fault analysis module 3, a simulation module 4 and a detection output module 5

The circuit sampling module 1 is configured to collect and pre-process various data imported into the MATLAB platform and the Simulink platform.

The line protection device 2 is configured to perform corresponding protection operations such as tripping or alarming when a fault occurs in the power distribution network, determine, according to different protection operations of the protection device, an approximate section in which the fault occurs, and number sections of the power grid.

The fault analysis module 3 is configured to analyze a fault location and a fault resistance value, and determine an approximate fault area.

The simulation module 4 is configured to acquire fault detection data through the Artificial Tree intelligent optimization algorithm by using the Simulink platform and display a simulation result.

The detection output module 5 is configured to, according to the simulation result, select part of the data to detect accuracy of power grid fault detection by the line neural network, analyze and report adaptability.

In this application, by utilizing the MATLAB platform, an improved wavelet threshold denoising method is used to remove noise sources in the signals to establish a power grid fault model, improving signal acquisition accuracy; simulation software is run for simulation, and a power grid fault model is established based on switch quantities to obtain a power grid fault information decision table; a neural network is trained for detecting the section where the fault occurs, and a divide-and-conquer strategy is adopted for complex power grids, so that the line topology structure can be flexible and changeable. This not only improves the accuracy and reliability of power grid fault diagnosis, but also can detect the fault when there is mal-operation information in the fault information, thereby achieving the effect of locating the fault area in the power grid and effectively enhancing the capability of detecting the fault in the power grid.

What is claimed is:

1. A multi-fault diagnosis method for a power distribution network, comprising:
performing short-circuit fault analysis on lines of the power distribution network by using a MATLAB platform to obtain an electrical quantity-based fault information decision table;
performing modeling and simulation on the electrical quantity-based fault information decision table by using a Simulink platform, and acquiring output training data of a neural network of the power distribution network;
denoising and collecting the output training data of the neural network by using a wavelet transformation method, and forming a related fault information decision table as a training sample of the neural network; and
optimizing weights and thresholds of the neural network by using an improved Artificial Tree intelligent optimization algorithm to satisfy a requirement related to error accuracy by means of iteration, selecting a part of the data as fault data, and using the trained neural network to perform fault detection;
wherein performing the short-circuit fault analysis on the lines of the power distribution network by using the MATLAB platform to obtain the electrical quantity-based fault information decision table comprises:
collecting, by the MATLAB platform, a zero-sequence current signal, a zero-sequence power signal and a zero-sequence admittance signal generated after a low-current ground short circuit fault in the lines of the power distribution network, and forming the electrical quantity-based fault information decision table based on the three types of information; and
performing the fault analysis based on the zero-sequence current signal, the zero-sequence power signal and the zero-sequence admittance signal by using a sampling mode with a mixture of discrete sampling time and continuous sampling time, wherein performing the fault analysis based on the zero-sequence current signal, the zero-sequence power signal and the zero-sequence admittance signal by using the sampling mode with a mixture of discrete sampling time and continuous sampling time comprises:
sampling and storing a positive zero-sequence current and a negative zero-sequence current at one of two terminals of each of the lines;
selecting a sampled current within a time window of fixed length as a line reference current, comparing a dynamic sampled current with the line reference current, and solving a correlation coefficient between the dynamic sampled current and the line reference current in real time by using an improved Pearson method; and
setting a correlation coefficient threshold, determining which one of magnitudes of the correlation coefficient and the threshold set is larger, and outputting a line where the fault is located and a type of the fault;
wherein the improved Pearson method adopts a cumulative value of the line correlation coefficient to perform correlation coefficient analysis for fault detection, and the improved Pearson method comprises:
defining movable window values T_{det} and T_{loc} within the time window of fixed length, and comparing a sampled current in T_{det} with a steady-state reference current to detect a fault of a direct current micro-grid, wherein end fixed moments of T_{det} and T_{loc}, are t₁ and t₂ respectively, and a relational expression between T_{det} and T_{loc} is as follows:
$${n}_{s} / {f}_{s} \leq {T}_{loc} \leq {T}_{0} \leq {T}_{det} ,$$
where fₛ is a sampling frequency of a line current, nₛ is a number of sampling points, and T₀ is duration from a time t₀ when the fault occurs to the time t₂ when the fault is detected;
performing the correlation coefficient analysis for fault detection by using the cumulative value of the line correlation coefficient, wherein an i^{th} comparison value of a steady-state reference current curve and an i^{th} comparison value of a sampled current curve are expressed as P_{1_i} and P_{2_i};
$$\{ \begin{matrix}{P}_{1 \_ i} = {\sum }_{j = 1}^{i} {I}_{ref \_ j} \\ {P}_{2 \_ i} = {\sum }_{j = 1}^{i} {I}_{sam \_ j}\end{matrix} \underline{.}$$
where I_{ref_j} is an i^{th} transient line current, and I_{sam_j} is an i^{th} sampled line current;
introducing an adjustment factor p to optimize the correlation coefficient in the Pearson method,
wherein an expression of the adjustment factor p is as follows:
$$p = 2 \times [ 1 - {( 1 + {- \vert {\sum }_{i = 1}^{n} \vert {P}_{1 \_ i} - {P}_{2 \_ i} \vert {/}_{n} \vert}^{} )}^{- 1} ] \underline{.}$$
where [symbol] is a mathematical constant and is expressed as a base of natural logarithm, and n is a total number of points at which the steady-state reference current curve and the sampled current curve are compared; and
optimizing the correlation coefficient r according to the adjustment factor p, wherein an expression of the correlation coefficient r is as follows:
$$\begin{matrix}\underline{r = p \times {r}_{0} , and} \\ {r}_{0} = \frac{{\sum }_{i = 1}^{n} [ ( {P}_{1 \_ i} - \frac{1}{n} {\sum }_{j = 1}^{n} {P}_{1 \_ i} ) ( ( {P}_{2 \_ i} - \frac{1}{n} {\sum }_{j = 1}^{n} {P}_{2 \_ i} ) ]}{\sqrt{{\sum }_{j = 1}^{n} {( {P}_{1 \_ i} - \frac{1}{n} {\sum }_{j = 1}^{n} {P}_{1 \_ i} )}^{2}} \sqrt{{\sum }_{j = 1}^{n} {( {P}_{2 \_ i} - \frac{1}{n} {\sum }_{j = 1}^{n} {P}_{2 \_ i} )}^{2}}}\end{matrix} ,$$
wherein a fault location and fault resistance are obtained according to the fault analysis, a model is constructed through the Simulink platform to output training data, and the training data is processed by the wavelet transformation method:
wherein a process of processing the training data by the wavelet transformation method comprises:
performing wavelet transformation on a training data signal f(t) with noise to obtain a set of decomposed wavelet coefficients;
performing threshold processing on the obtained set of decomposed wavelet coefficients by using a soft threshold function to obtain a set of estimated wavelet coefficients, wherein an expression of the soft threshold function ν(ω) is as follows:
$$\begin{matrix}\underline{υ ( ω ) = \{ \begin{matrix}( \vert ω \vert - T ) sign ( ω ) , \vert ω \vert \geq T \\ ω \times d \times {a}^{- {b ( \vert ω \vert - T )}^{2}} , \vert ω \vert < T\end{matrix} , and} \\ \underline{T = σ \sqrt{2 In ( m )} .}\end{matrix}$$
where sign is a sign function, ω is a wavelet coefficient, T is a threshold, σ is a noise intensity,
m is a signal length, d is an amplitude factor, and a and b are adjustment factors; and
adjusting d to enable the soft threshold function to be continuous at the threshold T and reduce an oscillation error generated to an original signal, and extracting a de-noised signal;
wherein a mean square error of the oscillation error is optimized by using the Artificial Tree algorithm to obtain the line neural network, and a process of optimization by using the Artificial Tree algorithm comprises:
using the mean square error (MSE) of the oscillation error as an objective function, sorting collected data, and preparing training samples and test samples;
setting relevant parameters of the Artificial Tree algorithm, determining a number SN of branches, a number D of spatial dimensions, and a number tₘₐₓ of iterations, and performing an initialization operation on the branches to generate an initial branch;
calculating a function value corresponding to each of the branches, and selecting, according to the function value, a best branch x_{best} of the branches and the function value f(x_{best}) corresponding to the best branch;
determining whether the requirement related to error accuracy is satisfied or whether the number of iterations is reached, and in response to not satisfying the requirement related to error accuracy and not reaching the number of iterations, preparing to enter an iterative optimization process by an iterated local search (IAT) algorithm;
in response to a search number reaching an upper limit of search number, performing a random operation to generate a new branch, and comparing the newly-generated branch with an old branch, in response to the newly-generated branch being better than the old branch, replacing the old branch with the newly-generated branch, and in response to the newly-generated branch being not better than the old branch, taking the old branch as the best branch; and
determining whether the best branch satisfies the requirement related to error accuracy or whether a current number of iterations reaches the number tₘₐₓ of iterations again.

2-7. (canceled)

8. The multi-fault diagnosis method for the power distribution network according to claim 1, wherein the relevant parameters of the Artificial Tree algorithm are set according to operation information of protection devices of the lines of the power distribution network and an area corresponding to a position where the fault occurs, to form a corresponding training sample of the neural network.

9. The multi-fault diagnosis method for the power distribution network according to claim 8, wherein the operation information of protection devices of the lines of the power distribution network comprises power grid signals based on switch quantities, and power grid switch operations are numbered with 0 and 1.

10. (canceled)
